(19) United States
(12) Patent Application Publication
(10) Pub. No.: US 2021/0183627 A1
(43) Pub. Date: Jun. 17, 2021

(54) Apparatus For Reducing Wafer Contamination During ION-Beam Etching Processes

(71) Applicant: International Business Machines Corporation, Armonk, NY (US)

(72) Inventors: John Arnold, North Chatham, NY (US); Donald Canaperi, Bridgewater, CT (US); Cornelius Brown Peethala, Slingerlands, NY (US); Daniel Charles Edelstein, White Plains, NY (US)

(21) Appl. No.: 16/710,232

(22) Filed: Dec. 11, 2019

(51) Int. Cl. H01J 37/32; H01J 37/305; H01L 21/683; H01L 21/67

(52) U.S. Cl. CPC H01J 37/32495; H01J 37/3053; H01J 2237/3341; H01L 21/67069; H01J 37/32715; H01L 21/6833

(57) ABSTRACT

An ion beam etching tool comprises a chuck configured to electrostatically receive a wafer; a plasma source configured to introduce an ion beam to the wafer; and a shield on the chuck and configured to shield the chuck from the ion beam. The shield comprises a material that is configured to be one of removable from the wafer or inert with regard to a semiconductor device on the wafer.

### BACKGROUND

The exemplary embodiments described herein relate generally to semiconductor devices and methods for the fabrication thereof and, more specifically, to apparatuses and methods for reducing wafer contamination in the processing of semiconductor devices.

New memory elements are being implemented into current back-end-of-line (BEOL) processing. This implementation brings new challenges to BEOL processing with regard to wafer contamination. In such processing, a tool such as an ion beam etch (IBE) tool may be used. Due to its physical nature of material removal, IBE is often used for magneto-resistive random access memory (MRAM) magnetic tunnel junction (MTJ) stack patterning on wafers.

During IBE, a shield is located on an electrostatic chuck (ESC) to which the wafer is mounted, this shield being close to the wafer and possibly being a source of metal contamination. Because IBE etches all materials with limited differentiation, the IBE also etches any of the tool materials that it strikes including the ESC shield. Since the ESC shield is usually stainless steel, the stainless steel removed from the ESC shield is often deposited onto the wafer as a contaminant. Stainless steel is generally not soluble in known fabrication-friendly wet etches and therefore may be difficult or impossible to remove from the wafer. The resulting contaminating deposits are not acceptable to downstream tools and general fabrication contamination requirements.

### BRIEF SUMMARY

In one exemplary aspect, an ion beam etching tool comprises a chuck configured to electrostatically receive a wafer; a plasma source configured to introduce an ion beam to the wafer; and a shield on the chuck and configured to shield the chuck from the ion beam. The shield comprises a material that is configured to be one of removable from the wafer or inert with regard to a semiconductor device on the wafer.

In another exemplary aspect, an apparatus comprises a chamber comprising one or more walls; a grid located in the chamber; an electrostatic chuck located in the chamber and configured to receive a wafer; a plasma source configured to introduce ion beams through the grid and to the wafer received on the electrostatic chuck; a grid shield on the grid; and a chuck shield on the electrostatic chuck and configured to shield the electrostatic chuck from the ion beams. The chuck shield comprises one or more of titanium, aluminum, cobalt, tantalum nitride, titanium nitride, magnesium, molybdenum, tantalum, tungsten, or alloys thereof.

In another exemplary aspect, an apparatus comprises a chamber comprising one or more walls; a grid located in the chamber; an electrostatic chuck located in the chamber and configured to receive a wafer; a plasma source configured to introduce ion beams through the grid and to the wafer received on the electrostatic chuck; a grid shield on the grid; and a chuck shield on the electrostatic chuck. The chuck shield comprises at least one of silicon or silicon dioxide.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 is a schematic representation of an IBE chamber illustrating possible sources of contaminants that may be deposited onto a wafer during an IBE process;

FIG. 2 is schematic representation of the re-deposition of contaminants onto a wafer from an ESC shield;

FIGS. 3A and 3B are scanning electron micrographs of a contaminated wafer;

FIGS. 4 and 5 are schematic representations of the redistribution of sputtered material from ion beams at different angles of incidence;

FIG. 6 is a schematic representation of the re-deposition of chamber material as a contaminant on a wafer;

FIG. 7 is a schematic representation of the re-deposition of material as a contaminant on a wafer due to scattering of the sputtered material;

FIG. 8 is a schematic representation of an IBE chamber illustrating an ESC shield fabricated from one example of a material used in an IBE process;

FIG. 9 is a schematic representation of an IBE chamber illustrating an ESC shield having plates fabricated from the example material of FIG. 8;

FIG. 10 is a schematic representation of an IBE chamber illustrating an ESC shield coated with the example material of FIG. 8;

FIG. 11 is a schematic representation of an IBE chamber illustrating chamber components that are fabricated using the example material of FIG. 8;

FIG. 12 is a schematic representation of an IBE chamber in which various chamber components comprise plates fabricated from the example material of FIG. 8;

FIG. 13 is a schematic representation of an IBE chamber in which various chamber components are coated with a material used in an IBE process;

FIG. 14 is a schematic representation of an IBE chamber illustrating an ESC shield fabricated using a material that is compatible with a wafer if sputtered onto the wafer in an IBE process;

FIG. 15 is a schematic representation of an IBE chamber illustrating an ESC shield having plates fabricated from a material that is compatible with a wafer if sputtered onto the wafer in an IBE process;

FIG. 16 is a schematic representation of an IBE chamber illustrating chamber components that are coated with a material that is compatible with a wafer if sputtered onto the wafer in an IBE process;

FIG. 17 is a schematic representation of an IBE chamber illustrating chamber components that are fabricated from a material that is compatible with a wafer if sputtered onto the wafer in an IBE process;

FIG. 18 is a schematic representation of an IBE chamber in which various chamber components include plates fabricated from a material that is compatible with a wafer if sputtered onto the wafer in an IBE process; and

FIG. 19 is a schematic representation of an IBE chamber in which various chamber components are coated with a material that is compatible with a wafer if sputtered onto the wafer in an IBE process.

### DETAILED DESCRIPTION

The word “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

In semiconductor processing, particularly with regard to BEOL processing of wafers, various devices may be used to implement memory elements. These devices may include wet-etching tools such as IBE tools. Ion beam etching is achieved in a process that involves directing a beam of charged particles (ions) at a target substrate with a suitably patterned mask in a high vacuum chamber. The IBE can be applied by using inert ions for a physical etching or milling process, or by using reactive ion species to increase material etching with a chemical/reactive component.

In the IBE processes described herein, multiple materials are exposed to the ion beam. When IBE is applied to a wafer (for example, a 300 millimeter (mm) wafer surface) during an MTJ stack patterning process in forming MRAM for a semiconductor device, the primary exposure is to the MTJ stack during the main etch process. Underlying dielectric materials may also be exposed to IBE during over-etching. Some exposure may also be applied to the various chamber components, such as the ESC shield, grids, grid shields, sensor shields, walls, and the like.

At ion energies necessary for MRAM processing, exposed materials are sputtered into the ambient environment. During IBE, a portion of the sputtered material re-deposits onto the wafer. A back side of the wafer, particularly in bevel regions, may be subjected to line-of-sight re-deposition from an ESC shield used in the process. A front side of the wafer may be subjected to line-of-sight re-deposition from the MTJ stack, hardmasks, and any underlying layers that are revealed during IBE. The line-of-sight deposition may be from the ion source, grids, shielding around grids, and/or the shutter assembly. All wafer surfaces are generally subjected to diffuse re-deposition of trace amounts of material that has been liberated from all surfaces and has been temporarily volatized or otherwise subjected to the scattering of sputtered material due to collisions with ambient gas in the chamber and/or incomplete sticking upon striking other surfaces.

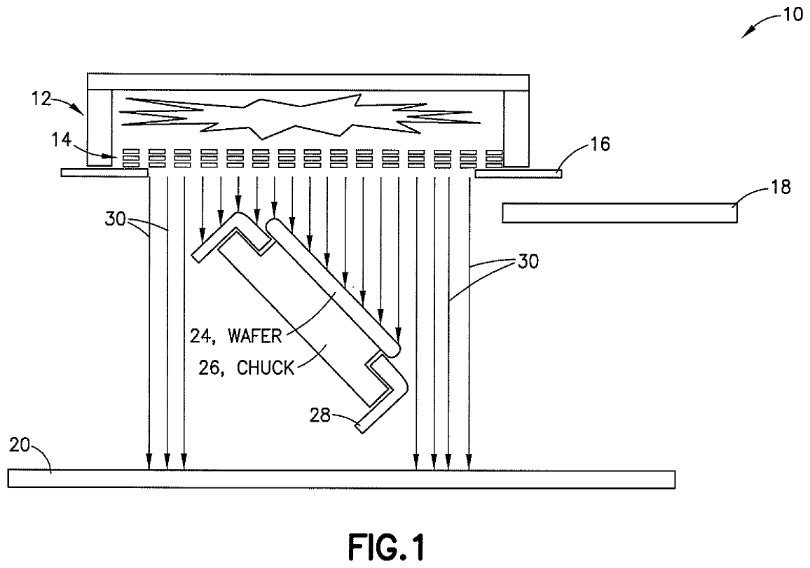

Referring to FIG. 1, an IBE chamber (which may be all or a portion of a semiconductor processing tool) is shown generally at 10 and is hereinafter referred to as “chamber 10.” Chamber 10 comprises a plasma source 12, grids 14, grid shields 16, a shutter 18, and chamber walls 20. A target substrate in the form of a wafer 24 is positioned on a tiltable ESC 26 in the chamber 10 with one or more ESC shields 28 positioned around the ESC. The wafer 24 may include an MTJ, masks, and/or other materials on the wafer surface. The wafer 24, the ESC 26, and the ESC shields 28 are positioned in the chamber 10 such that ion beams 30 from the plasma source 12 pass through the grids 14 and strike the wafer 24. In an IBE operation of the chamber 10, possible sources of contamination of the wafer 24 may be the grids 14, the grid shields 16, the shutter 18, the chamber walls 20, the ESC shields 28, as well as the MTJ, masks, and/or other materials on the wafer surface.

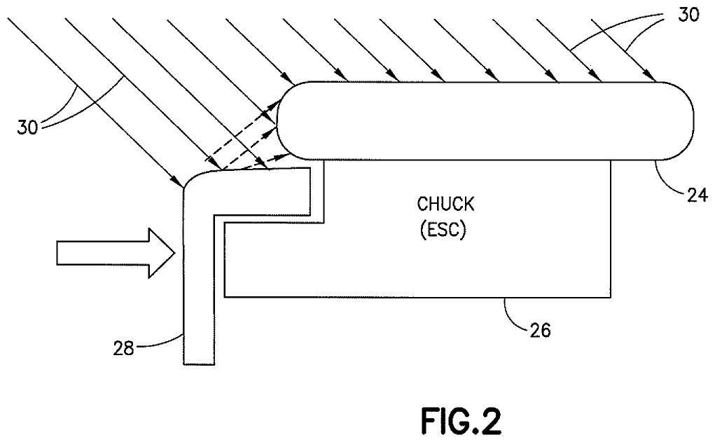

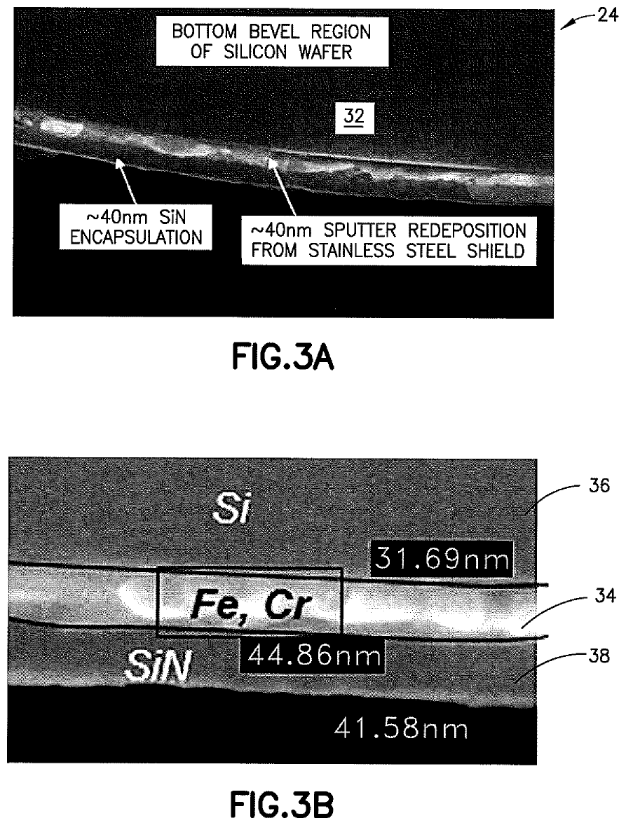

One mechanism of wafer contamination may be ESC shield re-deposition on a backside bevel of the wafer 24. Referring to FIG. 2, the ESC shield 28 tucks under the bottom edge of the wafer 24. During IBE at off-normal incidence (ion beams 30 come in at an angle possibly due to tilting of the wafer 24), material sputtered from the ESC shield 28 is re-deposited on the bevel region of the wafer 24, most heavily on the back side of the wafer 24. Typical materials from which ESC shields are fabricated include stainless steels. In FIG. 3A, a bottom bevel region 32 of a silicon wafer 24 shows an approximately 40 nanometer (nm) SiN encapsulation under which there is an approximately 40 nm re-deposition of sputter from a stainless steel ESC shield 28. In FIG. 3B, iron and chromium contamination 34 is shown between a silicon layer 36 and a silicon nitride layer 38.

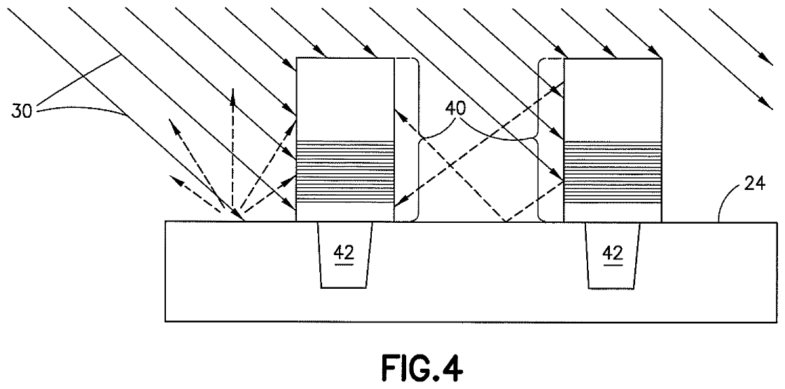

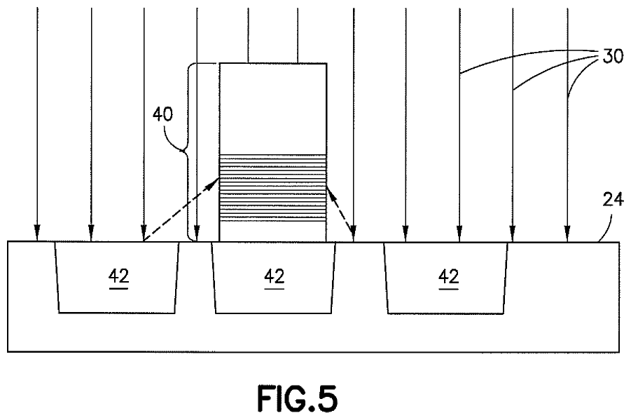

Another mechanism of wafer contamination may be due to the redistribution of sputtered material on a front side of the wafer 24. Referring to FIG. 4, material sputtered by the ion beams 30 and directed at the wafer 24 at an angle leaves surfaces of the wafer 24 with a distribution of angles. Sticking coefficients for materials in the magnetic devices such as MTJ pillars 40 and adjacent wiring 42 are typically in the range of 0.1 to 1.0. Thus, there may be a tendency for material sputtered from one location to re-deposit on other surfaces nearby. As shown in FIG. 5, material from the field around the MTJ pillar 40 may be re-deposited even if the ion beams 30 do not strike any of the surfaces of the MTJ pillar 40 before striking the surfaces of the wafer 24.

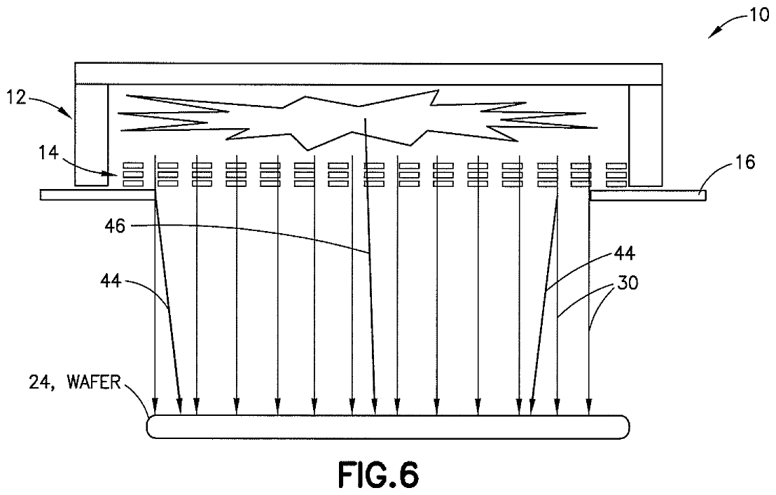

Referring to FIG. 6, another mechanism of wafer contamination may be due to the redistribution of chamber material on a front side of the wafer 24. As shown, material 44 sputtered from surfaces in the chamber exposed to the ion beams may be deposited at the front side of the wafer 24. Furthermore, materials 46 which have previously entered the plasma source 12 may be entrained in the ion beams 30 and driven to the front side of the wafer 24.

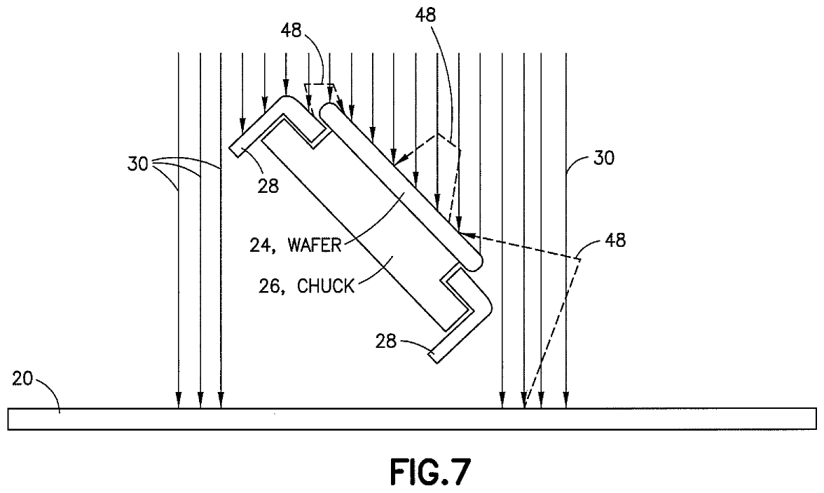

Another mechanism of wafer contamination may be due to the re-deposition of temporarily volatized material on exposed surfaces. As shown in FIG. 7, material 48 already on various surfaces may volatilize and collect on nearby surfaces. Sticking coefficients may be less than 1.0, and gas pressure is finite, so some sputtered material may migrate through the chamber and deposit on surfaces without a direct line of sight to the original plasma source 12. Also, some material sputtered by the ion beams 30 may migrate and deposit on surfaces without a direct line of sight to the location of the original sputtering event. Some material sputtered by the ion beams 30 may deposit onto the surface as usual.

The Table below is indicative of contamination of a bare silicon wafer with no MTJ stack, the wafer being processed through a typical IBE process. The wafer referred to in the Table is a 300 millimeter (mm) wafer with a blanket MTJ and patterning film stack, but without masking patterns. After the IBE process, the front surface of the wafer may be contaminated with materials from chamber components and the incoming film stack. Contamination is generally distributed across the wafer surface. Sample data for such contamination on a front side of a wafer after an IBE process is shown below:

TABLE
Materials remaining on wafer front side.

| Element | Likely Source | E10/at/cm² |
|---|---|---|
| Co | Incoming | 46.7 |
| Cr | Chamber walls and shields | 546.1 |
| Fe | Chamber walls and shields | 2238.6 |
| Ni | Chamber walls and shields | 145.1 |
| Mo | Grids | 314.2 |

Example embodiments disclosed herein are directed to reducing difficulties associated with removing contaminants in IBE processes, or reducing or eliminating the need for removal of contaminants, by changing materials from which an IBE chamber is constructed.

In a first exemplary embodiment, an IBE chamber is built with components made from materials that can be removed effectively from a wafer. Effective removal of these materials from a wafer may be carried out using processes that do not detrimentally affect device components on the wafer and that are compatible with device components. As used herein, compatible means that the processes carried out have no or minimal effect on the device components and/or are inert with regard to chemical and/or physical interactions with the device components. Such processes may include, for example, wet cleaning processes that do not damage memory elements or other device components and that are suitable with regard to downstream process flows.

In a second exemplary embodiment, an IBE chamber is built with one or more materials that can remain on the wafers during etching and through downstream processing of the wafer and are compatible, inert, and/or otherwise do not interfere with the performance of the final device.

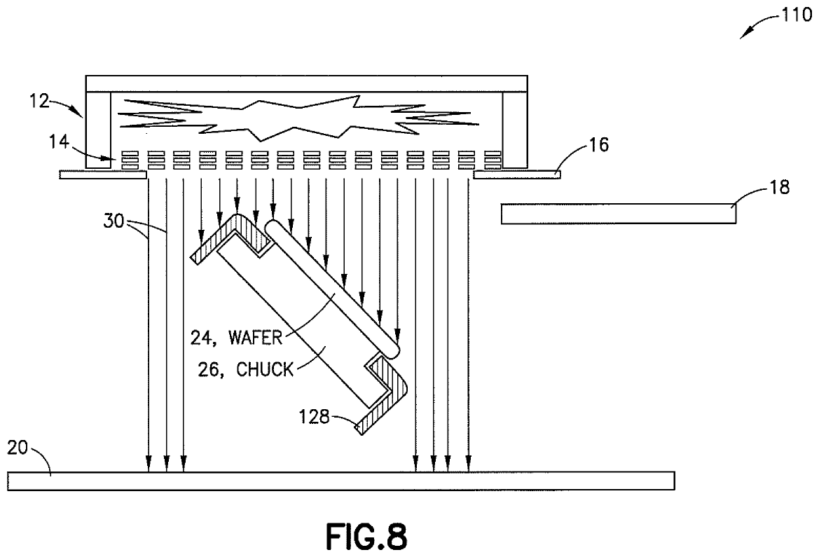

Referring to FIG. 8, one example of the first exemplary embodiment is shown generally at 110 and is referred to as “chamber 110.” In chamber 110, an ESC shield 128 is fabricated as a unitary piece from titanium or titanium alloy. The ESC shield 128 of chamber 110 is not limited to titanium, however, as other wet-etchable or wet-strippable materials such as Al, Co, TaN, TiN, Mg, Mo, Ta, W, alloys thereof, and the like may also or alternatively be used depending upon the apparatus design, materials, compatibility requirements, and other user requirements. Use of titanium (or other materials) as the ESC shield 128 may result in less sputtering of material (as compared to typical materials) or marginal amounts of material sputtering during an IBE process.

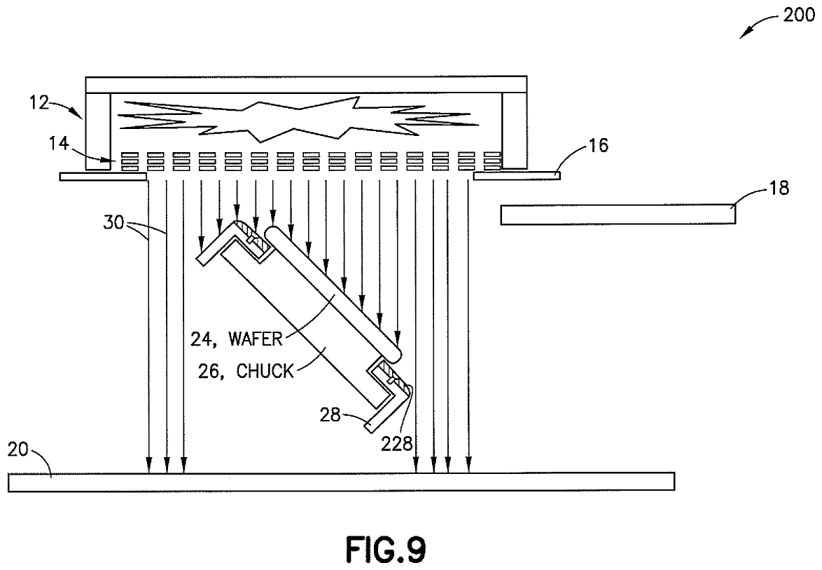

Referring to FIG. 9, another example of the first exemplary embodiment is shown generally at 200 and is referred to as “chamber 200.” In chamber 200, surfaces of an ESC shield 28 proximate the wafer 24 may be covered with titanium or other wet-etchable or wet-strippable material. As can be seen, the ESC shield 28 has a plate 228 thereon. The ESC shield 28 may be attached to the ESC 26 using fasteners, and the plate 228 may be attached to the ESC shield 28 using other fasteners.

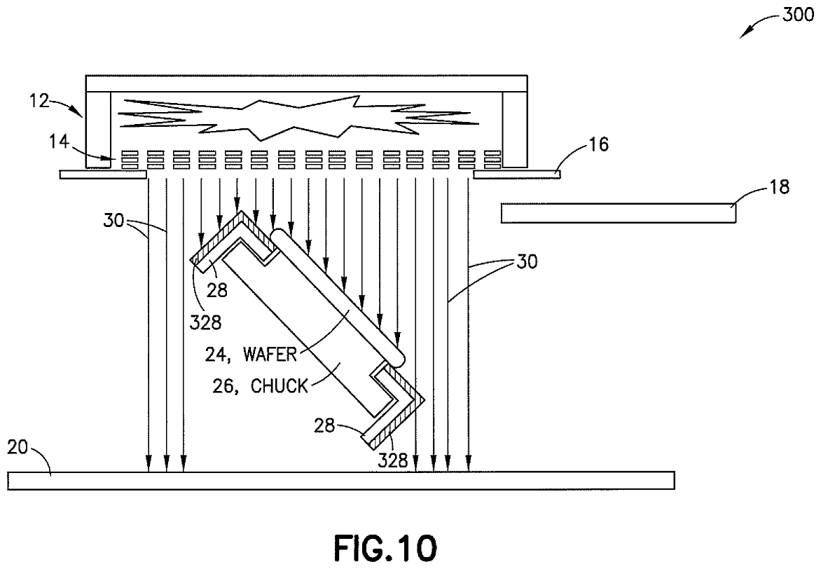

Referring to FIG. 10, another example of the first exemplary embodiment is shown generally at 300 and is referred to as “chamber 300.” In chamber 300, the ESC shield 28 may be coated with titanium or other wet-etchable or wet-strippable material. As can be seen, the ESC shield 28 has a coating 328 adhered to surfaces thereof. The coating 328 may be deposited using any suitable technique such as, for example, a plating technique, evaporation, physical vapor deposition (PVD), chemical vapor deposition (CVD), atomic layer deposition (ALD), plasma arc deposition, combinations of the foregoing techniques, or variations of any one or more of the foregoing techniques.

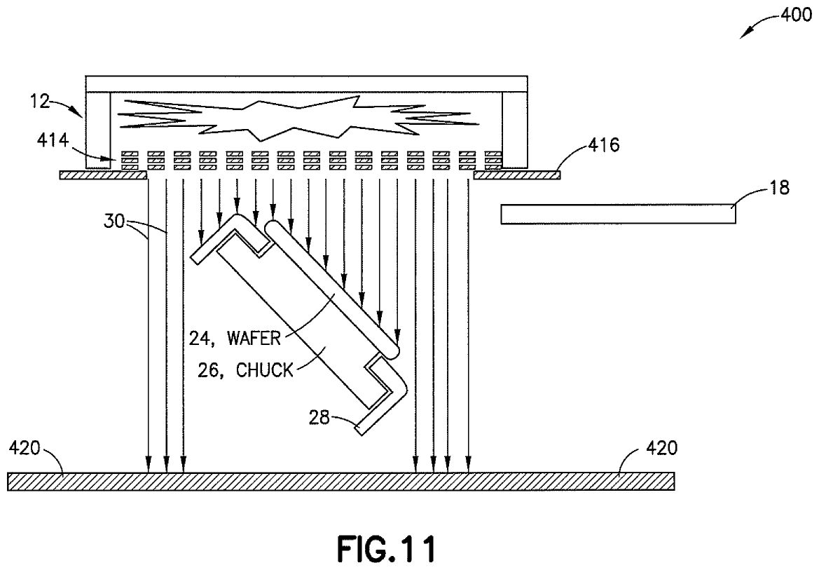

Referring to FIG. 11, another example of the first exemplary embodiment is shown generally at 400 and is referred to as “chamber 400.” In chamber 400, walls 420 of the chamber 400 that are exposed to ion beams 30 are fabricated from titanium (or other wet-etchable material). The chamber 400 is not limited to walls 420 being made of such a material, however, as other components including, but not limited to, grid shields 416 and grids 414 may be fabricated from such materials.

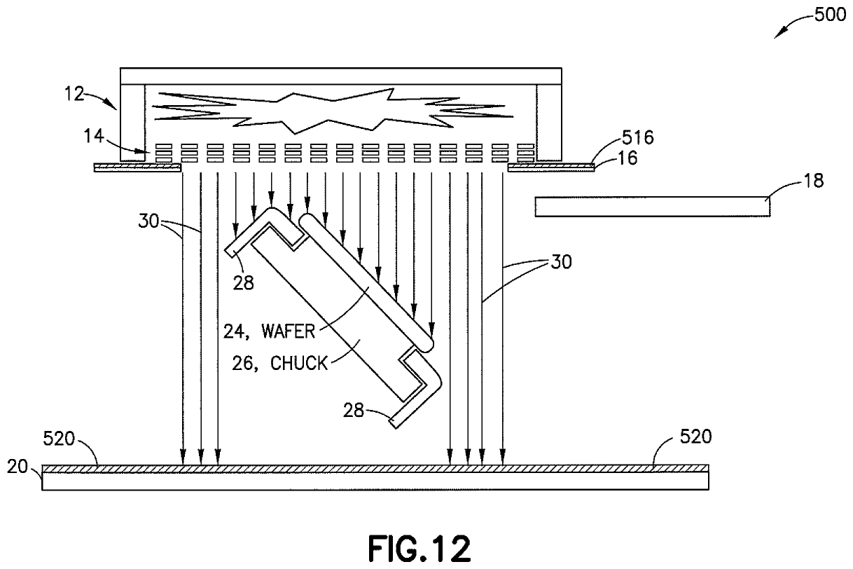

Referring to FIG. 12, in another example of the first exemplary embodiment of a chamber 500, surfaces of walls 20 may be covered with a plate 520 of titanium or other wet-etchable or wet-strippable material. Also, grid shields 16 may be covered with a plate 516 of titanium or other wet-etchable or wet-strippable material.

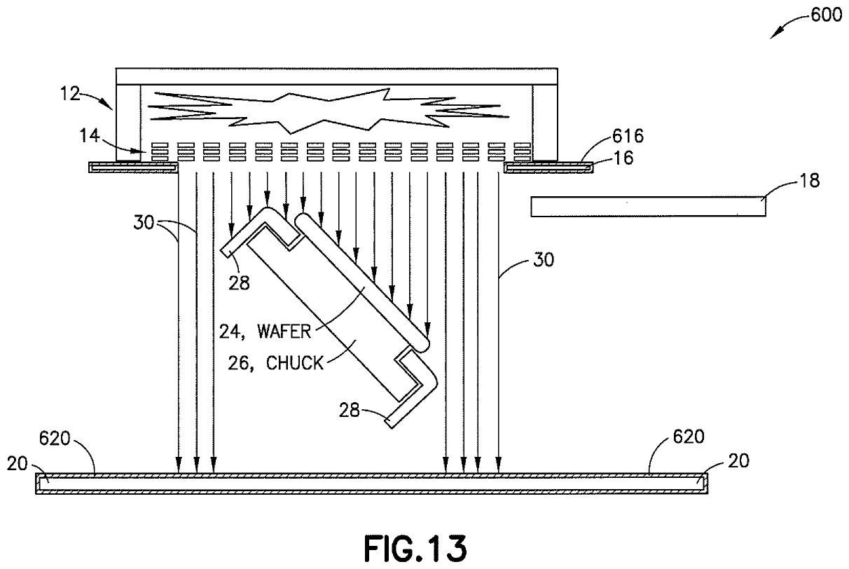

Referring to FIG. 13, in another example of the first exemplary embodiment of a chamber 600, walls 20 may have a coating 620 of titanium or other wet-etchable or wet-strippable material, and grid shields 16 may have a coating 616 of titanium or other wet-etchable or wet-strippable material. As can be seen, the coating 620 may be disposed on the walls 20 such that the coating 620 is adhered to surfaces of the walls 20, and the coating 616 may be disposed on the grid shields 16 such that the coating 616 is adhered to surfaces of the grid shields 16. The coating 616 may be deposited using any suitable technique such as, for example, a plating technique, evaporation, PVD, CVD, ALD, plasma arc deposition, combinations of the foregoing techniques, or variations of any one or more of the foregoing techniques.

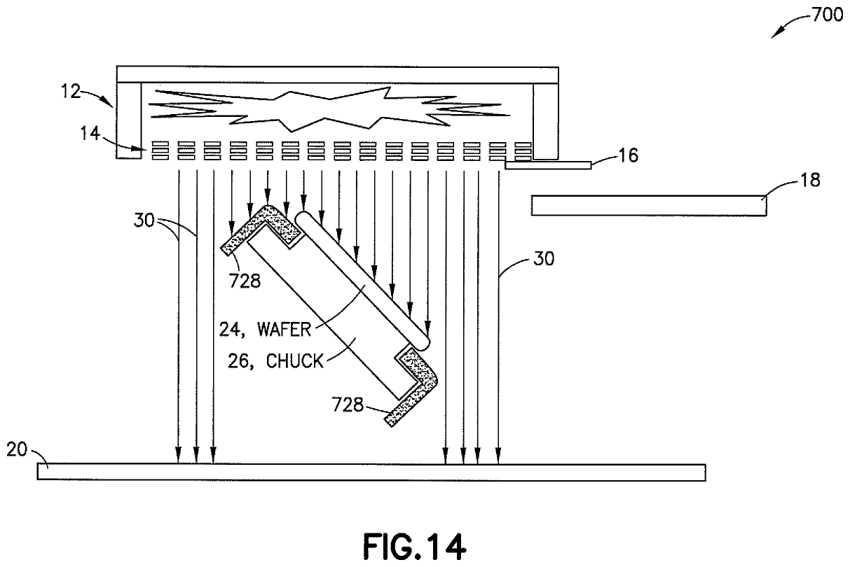

Referring to FIG. 14, one example of the second exemplary embodiment is shown generally at 700 and is referred to as “chamber 700.” In chamber 700, an ESC shield 728 may be fabricated from a material that can remain on the wafer 24 after the IBE process is complete. In particular, the ESC shield 728 may be constructed as a unitary piece from silicon, silicon dioxide, or any other material that is suitable for remaining on the wafer 24 upon completion of the IBE process.

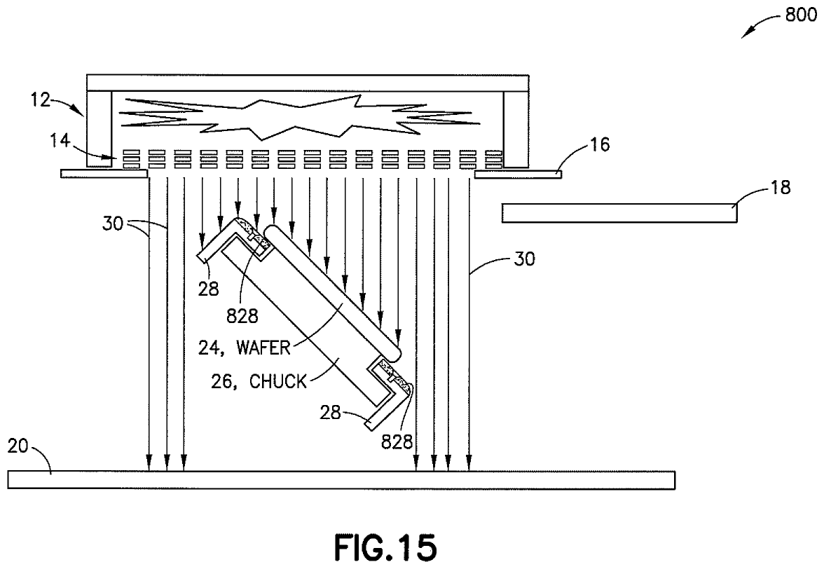

Referring to FIG. 15, another example of the second exemplary embodiment is shown generally at 800 and is referred to as “chamber 800.” In chamber 800, surfaces of an ESC shield 28 proximate the wafer 24 may be covered with silicon, silicon dioxide, or any other material that is suitable for remaining on the wafer 24. As can be seen, the ESC shield 28 has a plate 828 thereon. The ESC shield 28 may be attached to the ESC 26 using fasteners, and the plate 828 may be attached to the ESC shield 28 using other fasteners.

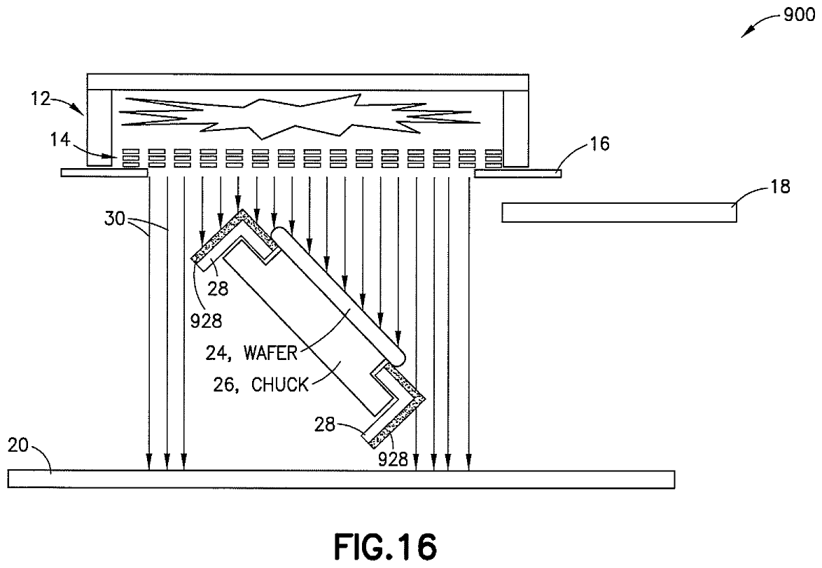

Referring to FIG. 16, another example of the second exemplary embodiment is shown generally at 900 and is referred to as “chamber 900.” In chamber 900, the ESC shield 28 may include a coating 928 of silicon, silicon dioxide, or any other material that is suitable for remaining on the wafer 24. The coating 928 is adhered to surfaces of the ESC shield 28. The coating 928 may be deposited using any suitable technique such as, for example, a plating technique, evaporation, PVD, CVD, ALD, plasma arc deposition, combinations of the foregoing techniques, or variations of any one or more of the foregoing techniques.

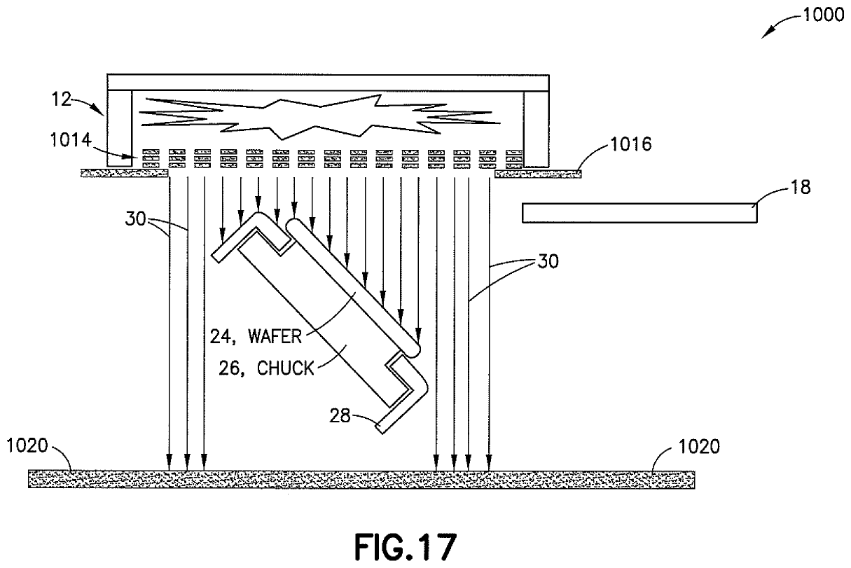

Referring to FIG. 17, another example of the second exemplary embodiment is shown generally at 1000 and is referred to as “chamber 1000.” In chamber 1000, walls 1020 of the chamber 1000 that are exposed to ion beams 30 are fabricated from silicon, silicon dioxide, or any other material that is suitable for remaining on the wafer 24. The chamber 1000 is not limited to wall 1020 being made of such a material, however, as other components including, but not limited to, grid shields 1016 and grids 1014 may be fabricated from such materials.

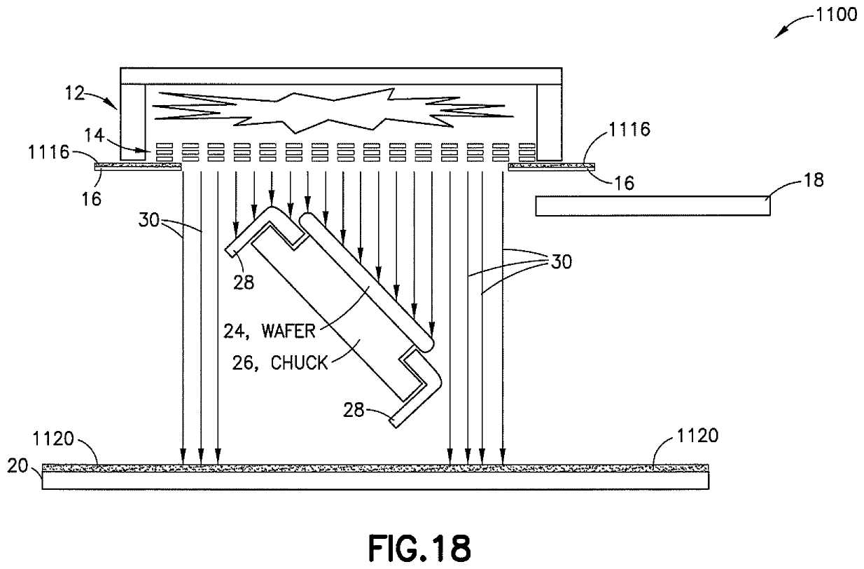

Referring to FIG. 18, another example of the second exemplary embodiment is shown generally at 1100 and is referred to as “chamber 1100.” In chamber 1100, surfaces of walls 20 may be covered with a plate 1120 of silicon, silicon dioxide, or any other material that is suitable for remaining on the wafer 24. Also, the grid shields 16 may be covered with a plate 1116 of silicon, silicon dioxide, or any other material that is suitable for remaining on the wafer 24.

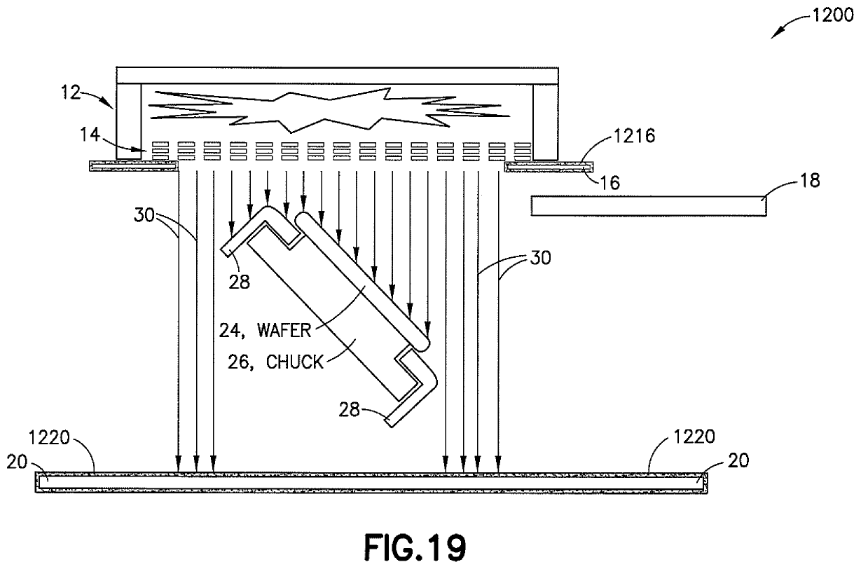

Referring to FIG. 19, another example of the second exemplary embodiment is shown generally at 1200 and is referred to as “chamber 1200.” In chamber 1200, walls 20 and grid shields 16 may be coated with silicon, silicon dioxide, or any other material that is suitable for remaining on the wafer 24. As can be seen, a coating 1220 may be disposed on the walls 20, the coating 1220 being adhered to surfaces of the walls 20. Also, a coating 1216 may be disposed on the grid shields 16, the coating 1216 being adhered to surfaces of the grid shields 16. The coating 1216 may be deposited using any suitable technique such as, for example, a plating technique, evaporation, PVD, CVD, ALD, plasma arc deposition, combinations of the foregoing techniques, or variations of any one or more of the foregoing techniques.

Referring now to all the Figures, in one example, an ion beam etching tool comprises a chuck configured to electrostatically receive a wafer; a plasma source configured to introduce an ion beam to the wafer; and a shield on the chuck and configured to shield the chuck from the ion beam. The shield comprises a material that is configured to be one of removable from the wafer or inert with regard to a semiconductor device on the wafer.

The shield may comprise a unitary piece formed from one or more of titanium, aluminum, cobalt, tantalum nitride, titanium nitride, magnesium, molybdenum, tantalum, tungsten, or alloys thereof. The shield may comprise a unitary piece formed from at least one of silicon or silicon dioxide. The shield may include a plate fastened to and at least partially covering the shield or a coating adhered to and at least partially covering the shield, the plate or coating comprising one or more of titanium, aluminum, cobalt, tantalum nitride, titanium nitride, magnesium, molybdenum, tantalum, tungsten, or alloys thereof. The shield may include a silicon or silicon dioxide plate fastened to and at least partially covering the shield or a silicon or silicon dioxide coating adhered to and at least partially covering the shield. The ion beam etching tool may further comprise a chamber in which the chuck, the plasma source, and the shield are mounted. At least a portion of one or more walls defining the chamber may comprise one or more of titanium, aluminum, cobalt, tantalum nitride, titanium nitride, magnesium, molybdenum, tantalum, tungsten, or alloys thereof. At least a portion of one or more walls defining the chamber may comprise silicon or silicon dioxide.

In another example, an apparatus comprises a chamber comprising one or more walls; a grid located in the chamber; an electrostatic chuck located in the chamber and configured to receive a wafer; a plasma source configured to introduce ion beams through the grid and to the wafer received on the electrostatic chuck; a grid shield on the grid; and a chuck shield on the electrostatic chuck and configured to shield the electrostatic chuck from the ion beams. The chuck shield comprises one or more of titanium, aluminum, cobalt, tantalum nitride, titanium nitride, magnesium, molybdenum, tantalum, tungsten, or alloys thereof.

The chuck shield may be fabricated as a unitary piece from one or more of titanium, aluminum, cobalt, tantalum nitride, titanium nitride, magnesium, molybdenum, tantalum, tungsten, or alloys thereof. The chuck shield may include a plate fastened to and at least partially covering the chuck shield, the plate comprising one or more of titanium, aluminum, cobalt, tantalum nitride, titanium nitride, magnesium, molybdenum, tantalum, tungsten, or alloys thereof. The chuck shield may include a coating adhered to and at least partially covering the chuck shield, the coating comprising one or more of titanium, aluminum, cobalt, tantalum nitride, titanium nitride, magnesium, molybdenum, tantalum, tungsten, or alloys thereof. The apparatus may further comprise at least a portion of the one or more walls comprising one or more of titanium, aluminum, cobalt, tantalum nitride, titanium nitride, magnesium, molybdenum, tantalum, tungsten, or alloys thereof. The apparatus may further comprise at least one of the grid or the grid shield comprising one or more of titanium, aluminum, cobalt, tantalum nitride, titanium nitride, magnesium, molybdenum, tantalum, tungsten, or alloys thereof.

In another example, an apparatus comprises a chamber comprising one or more walls; a grid located in the chamber; an electrostatic chuck located in the chamber and configured to receive a wafer; a plasma source configured to introduce ion beams through the grid and to the wafer received on the electrostatic chuck; a grid shield on the grid; and a chuck shield on the electrostatic chuck. The chuck shield comprises at least one of silicon or silicon dioxide.

The chuck shield may be fabricated as a unitary piece from at least one of silicon or silicon dioxide. The chuck shield may include a silicon or silicon dioxide plate fastened to and at least partially covering the chuck shield. The chuck shield may include a silicon or silicon dioxide coating adhered to and at least partially covering the chuck shield. The apparatus may further comprise at least a portion of the one or more walls comprising silicon or silicon dioxide. The apparatus may further comprise at least one of the grid or the grid shield comprising silicon or silicon dioxide.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. An ion beam etching tool, comprising:
a chuck configured to electrostatically receive a wafer;
a plasma source configured to introduce an ion beam to the wafer; and
a shield on the chuck and configured to shield the chuck from the ion beam;
wherein the shield comprises a material that is configured to be one of removable from the wafer or inert with regard to a semiconductor device on the wafer.

2. The ion beam etching tool of claim 1, wherein the shield comprises a unitary piece formed from one or more of titanium, aluminum, cobalt, tantalum nitride, titanium nitride, magnesium, molybdenum, tantalum, tungsten, or alloys thereof.

3. The ion beam etching tool of claim 1, wherein the shield comprises a unitary piece formed from at least one of silicon or silicon dioxide.

4. The ion beam etching tool of claim 1, wherein the shield includes a plate fastened to and at least partially covering the shield or a coating adhered to and at least partially covering the shield, the plate or coating comprising one or more of titanium, aluminum, cobalt, tantalum nitride, titanium nitride, magnesium, molybdenum, tantalum, tungsten, or alloys thereof.

5. The ion beam etching tool of claim 1, wherein the shield includes a silicon or silicon dioxide plate fastened to and at least partially covering the shield or a silicon or silicon dioxide coating adhered to and at least partially covering the shield.

6. The ion beam etching tool of claim 1, further comprising a chamber in which the chuck, the plasma source, and the shield are mounted.

7. The ion beam etching tool of claim 6, wherein at least a portion of one or more walls defining the chamber comprises one or more of titanium, aluminum, cobalt, tantalum nitride, titanium nitride, magnesium, molybdenum, tantalum, tungsten, or alloys thereof.

8. The ion beam etching tool of claim 6, wherein at least a portion of one or more walls defining the chamber comprises silicon or silicon dioxide.

9. An apparatus, comprising:
a chamber comprising one or more walls;
a grid located in the chamber;
an electrostatic chuck located in the chamber and configured to receive a wafer;
a plasma source configured to introduce ion beams through the grid and to the wafer received on the electrostatic chuck;
a grid shield on the grid; and
a chuck shield on the electrostatic chuck and configured to shield the electrostatic chuck from the ion beams;
wherein the chuck shield comprises one or more of titanium, aluminum, cobalt, tantalum nitride, titanium nitride, magnesium, molybdenum, tantalum, tungsten, or alloys thereof.

10. The apparatus of claim 9, wherein the chuck shield is fabricated as a unitary piece from one or more of titanium, aluminum, cobalt, tantalum nitride, titanium nitride, magnesium, molybdenum, tantalum, tungsten, or alloys thereof.

11. The apparatus of claim 9, wherein the chuck shield includes a plate fastened to and at least partially covering the chuck shield, the plate comprising one or more of titanium, aluminum, cobalt, tantalum nitride, titanium nitride, magnesium, molybdenum, tantalum, tungsten, or alloys thereof.

12. The apparatus of claim 9, wherein the chuck shield includes a coating adhered to and at least partially covering the chuck shield, the coating comprising one or more of titanium, aluminum, cobalt, tantalum nitride, titanium nitride, magnesium, molybdenum, tantalum, tungsten, or alloys thereof.

13. The apparatus of claim 9, further comprising at least a portion of the one or more walls comprising one or more of titanium, aluminum, cobalt, tantalum nitride, titanium nitride, magnesium, molybdenum, tantalum, tungsten, or alloys thereof.

14. The apparatus of claim 9, further comprising at least one of the grid or the grid shield comprising one or more of titanium, aluminum, cobalt, tantalum nitride, titanium nitride, magnesium, molybdenum, tantalum, tungsten, or alloys thereof.

15. An apparatus, comprising:
a chamber comprising one or more walls;
a grid located in the chamber;
an electrostatic chuck located in the chamber and configured to receive a wafer;
a plasma source configured to introduce ion beams through the grid and to the wafer received on the electrostatic chuck;
a grid shield on the grid; and
a chuck shield on the electrostatic chuck;
wherein the chuck shield comprises at least one of silicon or silicon dioxide.

16. The apparatus of claim 15, wherein the chuck shield is fabricated as a unitary piece from at least one of silicon or silicon dioxide.

17. The apparatus of claim 15, wherein the chuck shield includes a silicon or silicon dioxide plate fastened to and at least partially covering the chuck shield.

18. The apparatus of claim 15, wherein the chuck shield includes a silicon or silicon dioxide coating adhered to and at least partially covering the chuck shield.

19. The apparatus of claim 15, further comprising at least a portion of the one or more walls comprising silicon or silicon dioxide.

20. The apparatus of claim 15, further comprising at least one of the grid or the grid shield comprising silicon or silicon dioxide.
